(19) United States
(12) Patent Application Publication
(10) Pub. No.: US 2025/0300627 A1
(43) Pub. Date: Sep. 25, 2025

(54) SERIES-CONNECTED ACOUSTIC RESONATORS

(71) Applicant: Qorvo US, Inc., Greensboro, NC (US)

(72) Inventor: Yazid Yusuf, Orlando, FL (US)

(21) Appl. No.: 19/047,708

(22) Filed: Feb. 7, 2025

Related U.S. Application Data
(60) Provisional application No. 63/568,221, filed on Mar. 21, 2024.

(51) Int. Cl. H03H 9/205; H03H 3/02; H03H 9/02; H03H 9/56

(52) U.S. Cl. CPC H03H 9/205; H03H 3/02; H03H 9/02086; H03H 9/564

(57) ABSTRACT

Series acoustic resonators are disclosed. In one aspect, ohmic losses from series-connected acoustic resonators may be reduced by vertically stacking film bulk acoustic wave resonators (FBARs). The resonators are connected serially using conductive rings around the peripheries of an air gap between the resonators. This arrangement allows current to flow in multiple directions through the electrode, effectively reducing the current such that the ohmic losses that are proportional to current squared are reduced. By reducing the ohmic losses, overall efficiency of the device is improved.

### PRIORITY APPLICATION

The present application claims priority to U.S. Provisional Patent Application Ser. No. 63/568,221, filed on Mar. 21, 2024, and entitled “SERIES-CONNECTED ACOUSTIC RESONATORS,” the contents of which are incorporated herein by reference in its entirety.

### BACKGROUND

### I. Field of the Disclosure

The technology of the disclosure relates generally to acoustic resonators such as may be used in acoustic filters for signal processing.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. With the advent of the myriad functions available to such devices, there has been increased pressure to find ways to improve the bandwidth available to send and receive data at the mobile communication device. One way more bandwidth has been made available is through the higher frequencies of later-generation cellular standards. These higher frequencies have created challenges for filters used to process signals to be transmitted. These challenges for the filters provide room for innovation.

### SUMMARY

Aspects disclosed in the detailed description include series-connected acoustic resonators. In particular, ohmic losses from series-connected acoustic resonators may be reduced by vertically stacking film bulk acoustic wave resonators (FBARs). The resonators are connected serially using conductive rings around the peripheries of an air gap between the resonators. This arrangement allows current to flow in multiple directions through the electrode, effectively reducing the current such that the ohmic losses that are proportional to current squared are reduced. By reducing the ohmic losses, the overall efficiency of the device is improved.

In this regard, in one aspect, an acoustic device is disclosed. The acoustic device includes a first acoustic resonator comprising a first electrode, a first piezoelectric layer, and a second electrode, wherein the first piezoelectric layer is sandwiched between the first electrode and the second electrode. The acoustic device also includes a second acoustic resonator positioned on top of the first acoustic resonator with an air cavity between the first acoustic resonator and the second acoustic resonator, the second acoustic resonator comprising: a third electrode, a second piezoelectric layer; and a fourth electrode, wherein the second piezoelectric layer is sandwiched between the third electrode and the fourth electrode. The acoustic device further includes conductive vias coupling the second electrode to the third electrode proximate exterior edges of both the second electrode and the third electrode; the conductive vias further help delimit the air cavity.

In another aspect, a method of forming an acoustic device is disclosed. The method includes forming a first acoustic resonator comprising a first electrode, a conductive bridge coupling a first end of the first electrode to a second end of the first electrode, a first piezoelectric layer, and a second electrode, wherein the first piezoelectric layer is sandwiched between the first electrode and the second electrode. The method also includes coupling a second acoustic resonator to the first acoustic resonator with an air cavity therebetween, wherein the coupling comprises using conductive vias coupling the second electrode to a third electrode proximate exterior edges of both the second electrode and the third electrode, the conductive vias further helping delimit the air cavity.

In another aspect, a communication device is disclosed. The wireless communication device includes receive circuitry and transmit circuitry coupled to the antenna. The transmit circuitry comprising a filter comprising: a first acoustic resonator comprising: a first electrode, a conductive bridge coupling a first end of the first electrode to a second end of the first electrode, a first piezoelectric layer, and a second electrode, wherein the first piezoelectric layer is sandwiched between the first electrode and the second electrode, and a second acoustic resonator positioned on top of the first acoustic resonator with an air cavity between the first acoustic resonator and the second acoustic resonator. The second acoustic resonator comprising a third electrode, a second piezoelectric layer. And a fourth electrode, wherein the second piezoelectric layer is sandwiched between the third electrode and the fourth electrode. The wireless communication device also includes conductive vias coupling the second electrode to the third electrode proximate exterior edges of both the second electrode and the third electrode; the conductive vias further help delimit the air cavity.

### BRIEF DESCRIPTION OF THE DRAWINGS

FIG. 1 is a cross-sectional elevational view of a conventional acoustic resonator having conductive loops on the electrodes to reduce ohmic losses;

FIG. 2A is a cross-sectional view of a conventional acoustic resonator;

FIG. 2B is a circuit equivalent to the acoustic resonator of FIG. 2A;

FIG. 3A is a cross-sectional view of two series-connected acoustic resonators;

FIG. 3B is a circuit equivalent to the acoustic resonator of FIG. 3A;

FIG. 3C is a simplified circuit equivalent to the circuit of FIG. 3B;

FIG. 3D is the circuit of FIG. 3C, but with a different arrangement;

FIG. 4A is a cross-sectional view of vertically stacked series-connected acoustic resonators according to aspects of the present disclosure;

FIGS. 4B and 4C are circuit equivalents of the series-connected acoustic resonators of FIG. 4A;

FIG. 4D is another view of the cross-sectional view of FIG. 4A with current flow highlighted;

FIG. 5 is a cross-sectional view of three vertically stacked acoustic resonators according to an alternate aspect of the present disclosure;

FIG. 6 is a flowchart illustrating an exemplary process for forming a vertical stack of series-connected acoustic resonators; and

FIG. 7 is a block diagram of a mobile terminal, which may include the vertically stacked series-connected acoustic resonators of FIGS. 4A-5 according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship between one element, layer, or region and another element, layer, or region, as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Aspects disclosed in the detailed description include series acoustic resonators. In particular, ohmic losses from series-connected acoustic resonators may be reduced by vertically stacking film bulk acoustic wave resonators (FBARs). The resonators are connected serially using conductive rings around the peripheries of an air gap between the resonators. This arrangement allows current to flow in multiple directions through the electrode, effectively reducing the current such that the ohmic losses that are proportional to current squared are reduced. By reducing the ohmic losses, the overall efficiency of the device is improved.

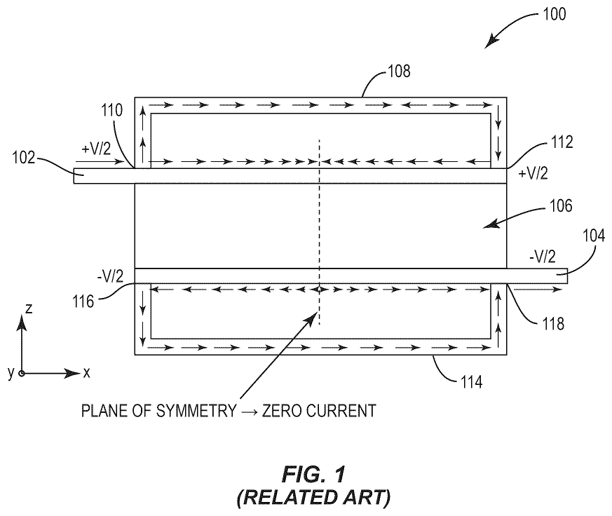

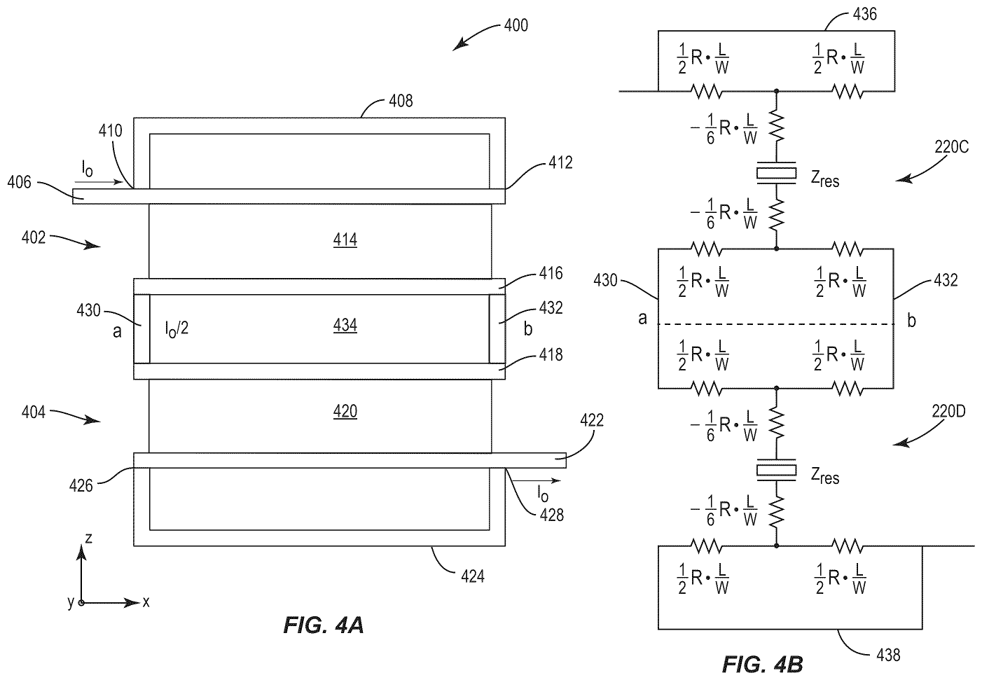

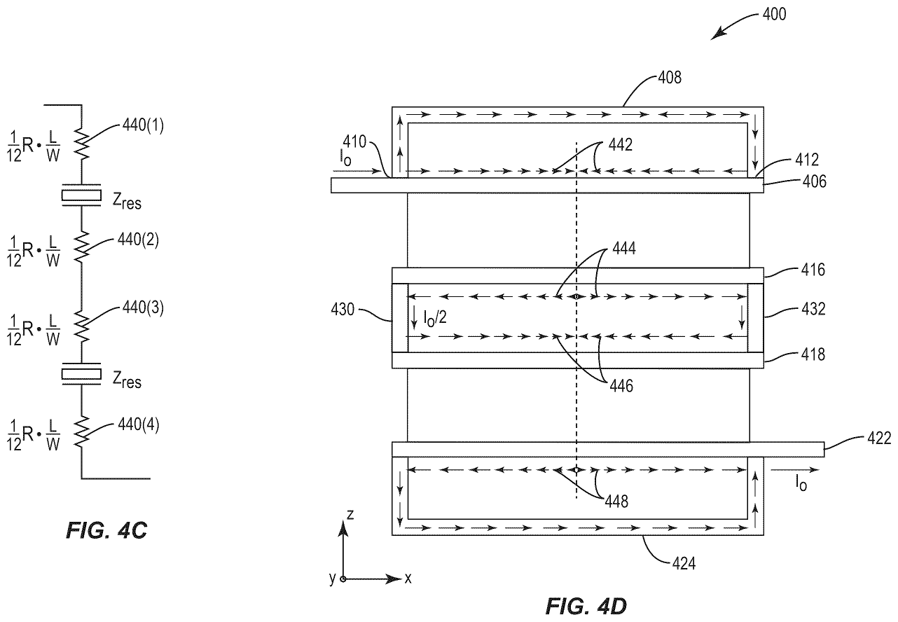

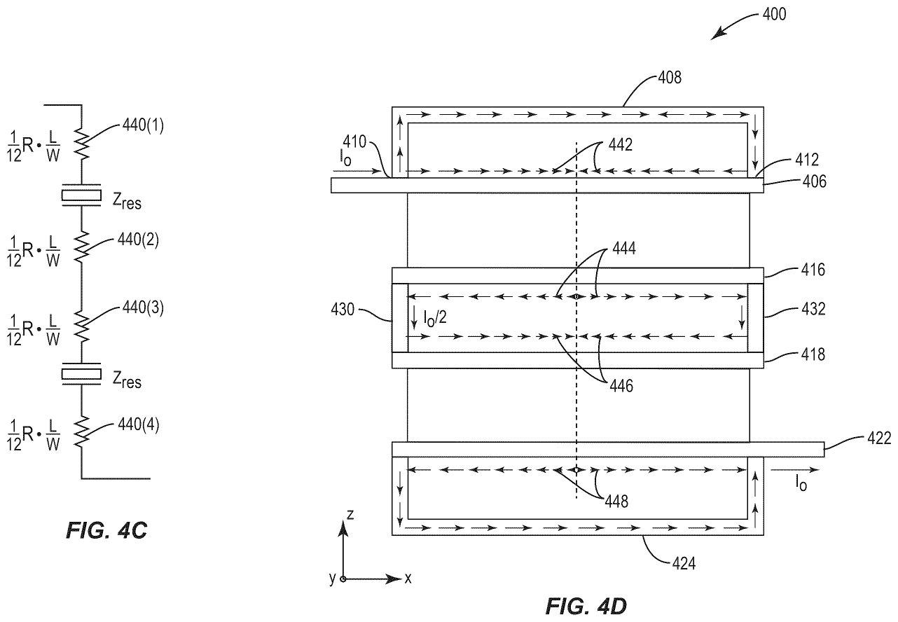

Before addressing aspects of the present disclosure, a brief overview of related work done by the author of the present disclosure is provided with reference to FIGS. 1-3D. A discussion of aspects of the present disclosure begins below with reference to FIG. 4A.

Filters are used commonly in wireless communication devices and particularly in transceivers, such as between a front-end module and an antenna. Current designs trend towards forming filters from acoustic resonators such as bulk acoustic wave (BAW) or surface acoustic wave (SAW) filters. Further, current wireless communication protocols trend to increasingly higher operating frequencies. The trend to higher operating frequencies places pressure on the acoustic elements for several reasons. Specifically, at higher frequencies, each element scales down to thinner and thinner elements, including electrodes on the acoustic resonators. However, such thinner elements generally increase the ohmic resistance of the electrodes. Additionally, as the size of the acoustic elements decreases, the resonators also become smaller while supporting higher power signals. This consolidation of size coupled with higher power signals means that there is a higher power density and correspondingly higher power loss per unit area due at least in part to ohmic resistance. One approach to reduce the power density is to cascade multiple resonators in series, but this comes at the expense of greater ohmic resistance. One approach that the author of the present disclosure co-authored can be found in commonly owned U.S. Pat. No. 11,528,007, which is hereby incorporated by reference in its entirety. That approach, better illustrated in FIG. 1, contemplates adding a conductive bridge to electrodes on an acoustic resonator to spread current flow, thereby reducing ohmic resistance.

In this regard, FIG. 1 is a cross-sectional view of an acoustic resonator 100. The acoustic resonator 100 includes a first electrode 102 and a second electrode 104 with a piezoelectric layer 106 therebetween. The first electrode 102 has a conductive bridge 108 that couples a first end 110 of the first electrode 102 to a second end 112 of the first electrode 102. Similarly, the second electrode 104 has a conductive bridge 114 that couples a first end 116 of the second electrode 104 to a second end 118 of the second electrode 104.

The presence of the conductive bridges 108, 114 cause current flow on the electrodes 102, 104 to be bidirectional, which in turn reduces a magnitude of the current, thereby reducing ohmic losses through the electrodes 102, 104. This approach has demonstrated approximately a four-fold reduction in ohmic resistance for an acoustic resonator. However, when more than one acoustic resonator 100 is arranged serially, as is common for filters, the sum of even these reduced ohmic resistances may negatively impact performance.

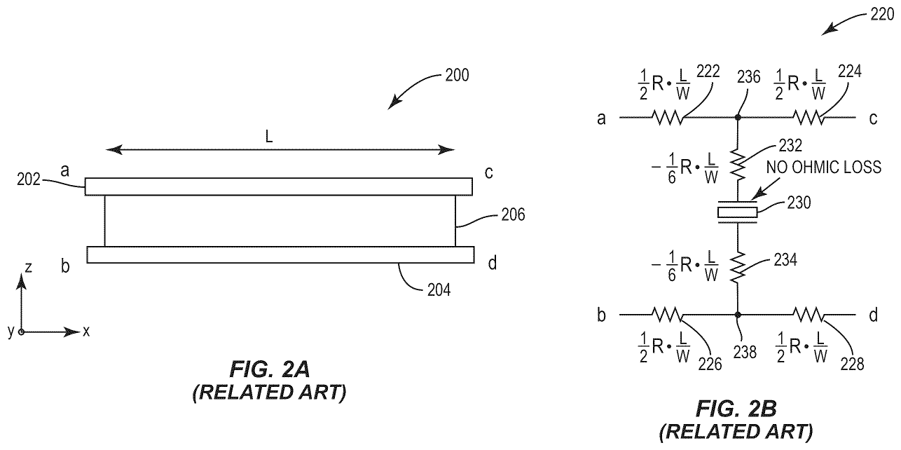

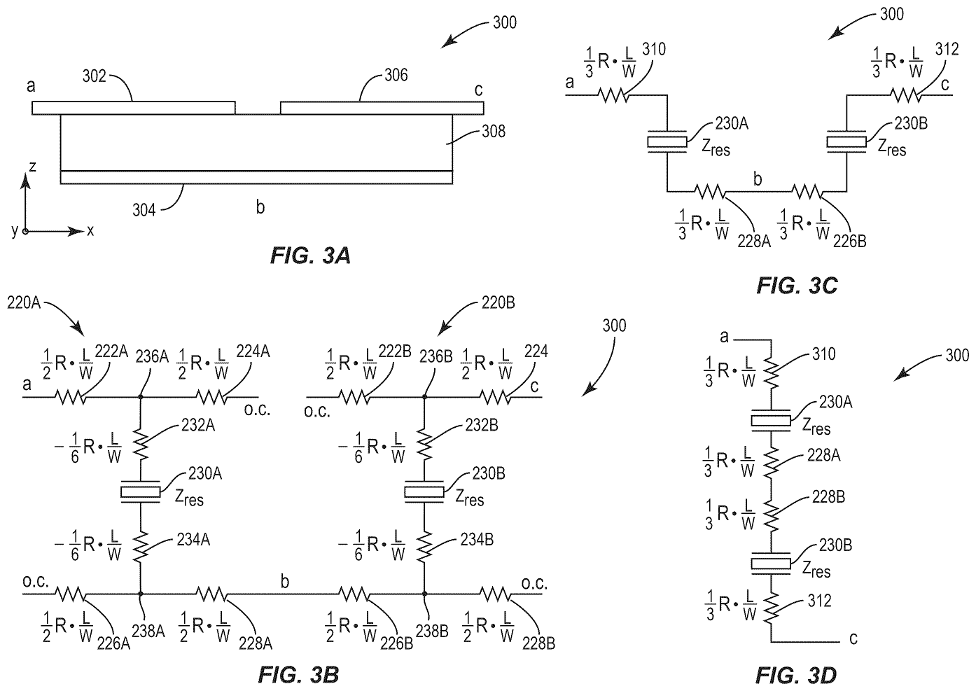

For the sake of helping understand how serial acoustic resonators may accumulate ohmic resistance, reference is made to FIGS. 2A-3D. The explanation provided with FIGS. 2A-3D assumes an acoustic resonator that is connected from two sides. This assumption is helpful in modeling and understanding the behavior of concern. Similar behavior can be seen in acoustic resonators connected on all four edges, but the behavior becomes more complex, and the modeling becomes substantially more complex. Accordingly, while this sort of two-dimensional explanation is used for simplicity, the skilled artisan will appreciate that the discussion can be extended to the three-dimensional aspects. With that caveat in mind, circuit equivalents of the acoustic resonators are provided to assist in showing the advantages of the present disclosure, beginning below with reference to FIG. 4A.

An acoustic resonator 200, illustrated in FIG. 2A has a first electrode 202 and a second electrode 204 with a piezoelectric layer 206 therebetween. The electrodes 202, 204 are assumed to be of equal size and have dimensions L by W, where L is in the x-axis and W is in the y-axis (and thus not shown in FIG. 2A). The edges a, b, c, and d of the electrodes 202, 204 are accessible. A circuit 220 is provided in FIG. 2B, where the circuit 220 is equivalent to the acoustic resonator 200.

In particular, the circuit 220 has resistors 222, 224 between the edges a and c. The circuit 220 has resistors 226, 228 between the edges b and d. The resonator 230 is assumed to be perfect, with no ohmic loss, but resistors 232, 234 couple the resonator 230 to nodes 236, 238 respectively.

As noted, resonators may be coupled in series, for example, as shown by cascaded resonator device 300 in FIG. 3A. The cascaded resonator device 300 includes a first electrode 302, an opposite electrode 304, and a second electrode 306. A piezoelectric layer 308 is positioned between electrodes 302, 306, and opposite electrode 304. In this case, there are only three contacts a, b, and c. The equivalent circuit for the cascaded resonator device 300 is shown in FIG. 3B with two circuits 220A, 220B coupled at contact b. Further, resistors 224A, 222B, 226A, and 226B are terminated at open circuits (o.c.). The structure of FIG. 3B can be simplified to the structure shown in FIG. 3C by eliminating the resistors 224A, 222B, 226A, and 226B with open circuit terminations. Likewise, resistors 222A and 232A combine into resistor 310, while resistors 224B and 232B combine into resistor 312. Note further that this structure can be rearranged, as shown in FIG. 3D.

As noted, the cumulative effectiveness of the various resistors in the cascaded resonator device 300 may negatively impact performance. This impact is exacerbated when more than two resonators are cascaded.

Aspects of the present disclosure contemplate expanding on the teachings of the '007 patent by vertically stacking multiple acoustic resonators and leveraging the proximity of the electrodes to create conductive bridges therefrom, as better seen in FIG. 4A. Again, the explanation provided is based on a two-dimensional structure but can be extended to a three-dimensional structure.

In this regard, FIG. 4A illustrates a resonator stack 400, where a first resonator 402 is stacked vertically (i.e., in the z-axis) over a second resonator 404. The first resonator 402 includes a top or, more generically, a first electrode 406 with a conductive bridge 408 connecting a first end 410 to a second end 412, thereby spreading the current flow across the first electrode 406, as better seen in FIG. 4D. The first electrode 406 is positioned on top (i.e., in the z-axis sense) of a piezoelectric layer 414. A bottom or, more generically, a second electrode 416 is positioned opposite the first electrode 406, sandwiching the piezoelectric layer 414 therebetween.

The second resonator 404 includes a top or, more generically, a third electrode 418 positioned on top (i.e., in the z-axis sense) of a second piezoelectric layer 420. A bottom or, more generically, a fourth electrode 422 is positioned opposite the third electrode 418, sandwiching the second piezoelectric layer 420 therebetween. A second conductive bridge 424 connects a first end 426 to a second end 428 of the fourth electrode 422, thereby spreading the current flow across the fourth electrode 422, as better seen in FIG. 4D.

Vertical conductors 430, 432 couple the second electrode 416 to the third electrode 418, sandwiching an air cavity 434 therebetween. The vertical conductors 430, 432 have the effect of splitting the current flow in the second electrode 416 as well as providing two input current sources for the third electrode 418. The net effect of this splitting and multiple inputs is to replicate the function of the bridge originally taught in the '007 patent. The actual current flow can be seen in FIG. 4D.

FIGS. 4B and 4C assist in an analysis of the ohmic resistance of the resonator stack 400. In effect, in FIG. 4B, two resonators 220C and 220D are stacked with short circuits 436 and 438 mirroring the bridges 408, 424. The resistor network of FIG. 4B may be simplified to the structure shown in FIG. 4C. Saliently, the resistors 440(1)-440(4) are another factor of four less ( 1/12 versus ⅓) than those illustrated in the comparable circuit of FIG. 3D. This difference represents a substantial reduction in ohmic resistance and makes stacking multiple series resonators more practical.

FIG. 4D is provided to highlight how the current flow is split, which helps reduce current (I) and thus helps reduce the ohmic resistance. Specifically, as expected, the conductive bridge 408 causes current 442 to split and flow through the first electrode 406 from both ends 410, 412. The vertical conductors 430, 432 also cause current 444 in the second electrode 416 to split and flow through both vertical conductors 430, 432, which in turn creates the two inputs for the third electrode 418, which means that current 446 is also split. The second conductive bridge 424 also splits the current 448 in the fourth electrode 422.

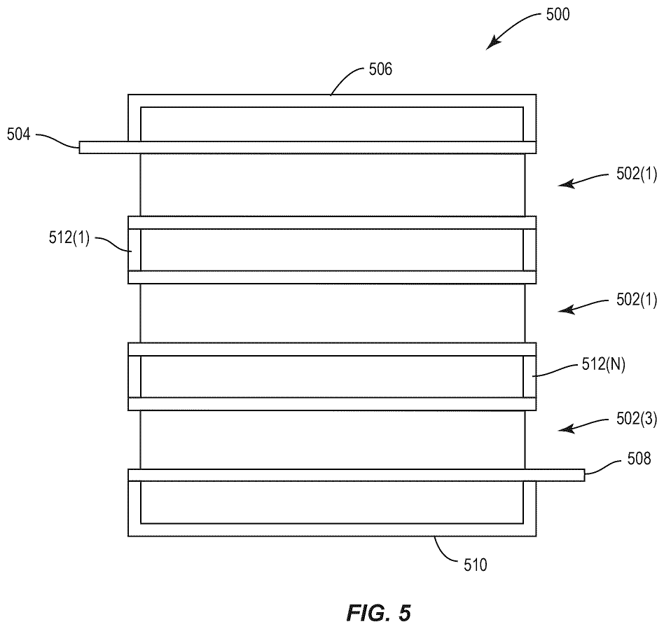

It should be appreciated that more than two resonators may be stacked and connected in this fashion, as better seen in FIG. 5, where stack 500 includes three resonators 502(1)-502(3). The top-most electrode 504 (in the z-axis sense) has a conductive bridge 506. Similarly, the bottom-most electrode 508 has a second conductive bridge 510. Other electrodes use adjacent electrodes as the bridge to split current flow.

FIG. 5 also has vias 512(1)-512(N). While it is possible that the vias 512(1)-512(N) are conductors like the vertical conductors 430, 432, it is also possible that the vias 512(1)-512(N) are made from a phase change material such as those described in “Phase Change Material (PCM) Technology for Microwave and mm-Wave Applications” by Mansour et al., Workshop at International Microwave Symposium (IMS 2023). Use of such PCM vias may allow switching resonators in or out of series or other connections (e.g., series to shunt or vice versa). In practice, micro heating elements are used to change a local temperature proximate the PCM, where such temperature changes cause the PCM to switch between a conductor and an insulator. Note that PCM may be used in the resonator stack 400.

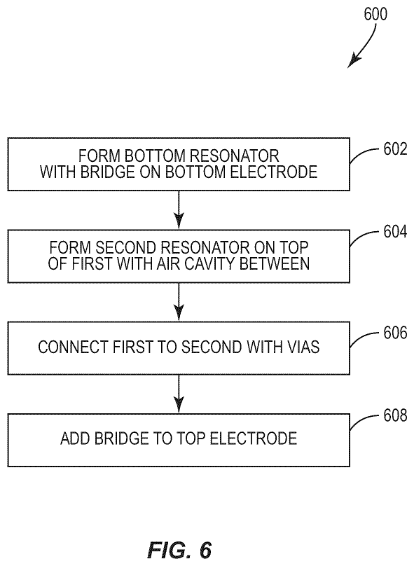

A process 600 for forming the vertically stacked series resonators of the present disclosure is provided with reference to FIG. 6. The process begins by forming a first or bottom resonator with a conductive bridge on a bottom electrode (block 602). A second resonator is formed on top of the first resonator with an air cavity between (block 604). The first resonator is coupled to the second resonator with vias (block 606), and a second conductive bridge is added to a top electrode of the second resonator (block 608).

The series acoustic resonators, according to aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

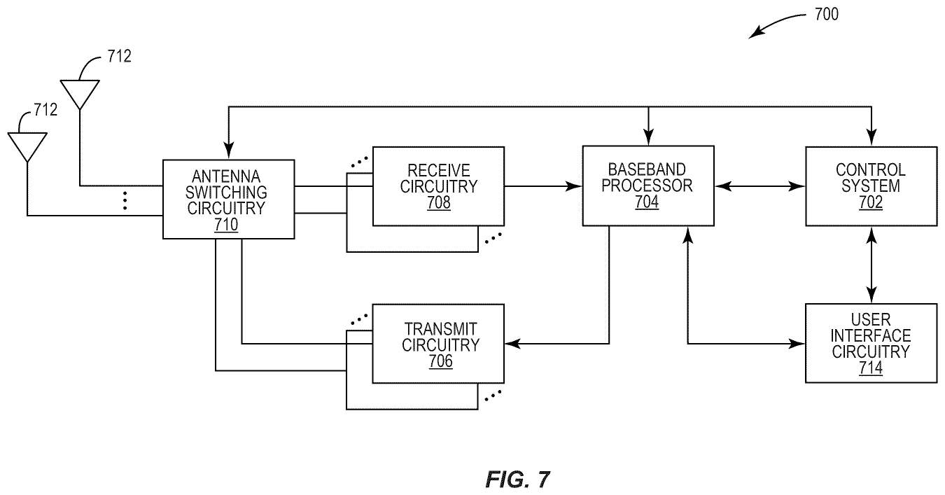

FIG. 7 is a schematic diagram of an exemplary communication device 700 wherein the stacked serial acoustic resonators can be provided. Herein, the communication device 700 can be any type of communication device, such as those listed above, as well as access points, base stations (e.g., eNB or gNB), and any other type of wireless communication devices that support wireless communications, such as cellular, wireless local area network (WLAN), Bluetooth, Ultra-wideband (UWB), and near field communications.

More particularly, the concepts described above may be implemented in various types of communication devices 700, such as mobile terminals, smart watches, tablets, computers, navigation devices, access points, and like wireless communication devices that support wireless communications, such as cellular, wireless local area network (WLAN), Bluetooth, and near field communications. The communication devices 700 will generally include a control system 702, a baseband processor 704, transmit circuitry 706, which may include filters having the acoustic resonators of the present disclosure, receive circuitry 708, antenna switching circuitry 710, multiple antennas 712, and user interface circuitry 714. In a non-limiting example, the control system 702 can be a field-programmable gate array (FPGA) or an application-specific integrated circuit (ASIC), as an example. In this regard, the control system 702 can include at least a microprocessor(s), an embedded memory circuit(s), and a communication bus interface(s). The receive circuitry 708 receives radio frequency signals via the antennas 712 and through the antenna switching circuitry 710 from one or more base stations. A low noise amplifier and a filter of the receive circuitry 708 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 704 processes the digitized received signal to extract the information or data bits conveyed in the received signal. This processing typically comprises demodulation, decoding, and error correction operations. The baseband processor 704 is generally implemented in one or more digital signal processors (DSPs) and ASICs.

For transmission, the baseband processor 704 receives digitized data, which may represent voice, data, or control information, from the control system 702, which it encodes for transmission. The encoded data is output to the transmit circuitry 706, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 712 through the antenna switching circuitry 710 to the antennas 712. The multiple antennas 712 and the replicated transmit and receive circuitries 706, 708 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. An acoustic device comprising:
a first acoustic resonator comprising:
a first electrode;
a first piezoelectric layer; and
a second electrode, wherein the first piezoelectric layer is sandwiched between the first electrode and the second electrode;
a second acoustic resonator positioned on top of the first acoustic resonator with an air cavity between the first acoustic resonator and the second acoustic resonator, the second acoustic resonator comprising:
a third electrode;
a second piezoelectric layer; and
a fourth electrode, wherein the second piezoelectric layer is sandwiched between the third electrode and the fourth electrode; and
conductive vias coupling the second electrode to the third electrode proximate exterior edges of both the second electrode and the third electrode, the conductive vias further help delimit the air cavity.

2. The acoustic device of claim 1, further comprising a conductive bridge coupling a first end of the first electrode to a second end of the first electrode.

3. The acoustic device of claim 1, wherein the conductive vias comprise a phase change material and are selectively conductive.

4. The acoustic device of claim 1, further comprising a third acoustic resonator stacked on top of the second acoustic resonator.

5. The acoustic device of claim 4, further comprising additional conductive vias coupling the second acoustic resonator to the third acoustic resonator.

6. The acoustic device of claim 1 integrated into a filter.

7. The acoustic device of claim 2, further comprising a second conductive bridge coupling a third end of the fourth electrode to a fourth end of the fourth electrode.

8. A method of forming an acoustic device, comprising;
forming a first acoustic resonator comprising:
a first electrode;
a conductive bridge coupling a first end of the first electrode to a second end of the first electrode;
a first piezoelectric layer; and
a second electrode, wherein the first piezoelectric layer is sandwiched between the first electrode and the second electrode; and
coupling a second acoustic resonator to the first acoustic resonator with an air cavity therebetween, wherein the coupling comprises using conductive vias coupling the second electrode to a third electrode proximate exterior edges of both the second electrode and the third electrode, the conductive vias further helping delimit the air cavity.

9. The method of claim 8, further comprising forming a second conductive bridge on the on a fourth electrode.

10. The method of claim 8, further comprising integrating the acoustic device into a filter.

11. The method of claim 10, further comprising integrating the filter into a transceiver.

12. The method of claim 8, further comprising adding a third acoustic resonator to the acoustic device.

13. The method of claim 8, wherein using conductive vias comprises using phase change material for the conductive vias.

14. A communication device comprising:
receive circuitry configured to receive incoming signals; and
transmit circuitry, the transmit circuitry comprising a filter comprising:
a first acoustic resonator comprising:
a first electrode;
a conductive bridge coupling a first end of the first electrode to a second end of the first electrode;
a first piezoelectric layer; and
a second electrode, wherein the first piezoelectric layer is sandwiched between the first electrode and the second electrode;
a second acoustic resonator positioned on top of the first acoustic resonator with an air cavity between the first acoustic resonator and the second acoustic resonator, the second acoustic resonator comprising:
a third electrode;
a second piezoelectric layer; and
a fourth electrode, wherein the second piezoelectric layer is sandwiched between the third electrode and the fourth electrode; and
conductive vias coupling the second electrode to the third electrode proximate exterior edges of both the second electrode and the third electrode, the conductive vias further help delimit the air cavity.

15. The communication device of claim 14, further comprising a second conductive bridge coupling a third end of the fourth electrode to a fourth end of the fourth electrode.

16. The communication device of claim 14, wherein the conductive vias comprise a phase change material and are selectively conductive.

17. The communication device of claim 14, further comprising a third acoustic resonator stacked on top of the second acoustic resonator.

18. The communication device of claim 17, further comprising additional conductive vias coupling the second acoustic resonator to the third acoustic resonator.

19. The communication device of claim 14, further comprising an antenna, the receive circuitry and the transmit circuitry coupled to the antenna.

20. The communication device of claim 14, wherein the communication device comprises a wireless communication device.
